(19) United States
(12) Patent Application Publication
(10) Pub. No.: US 2022/0109220 A1
(43) Pub. Date: Apr. 7, 2022

(54) POWER SPLITTER-COMBINER CIRCUITS IN 5G MM-WAVE BEAMFORMER ARCHITECTURES

(71) Applicant: Mobix Labs, Inc., Irvine, CA (US)

(72) Inventors: Oleksandr Gorbachov, Irvine, CA (US); Lisette L. Zhang, Irvine, CA (US)

(21) Appl. No.: 17/488,697

(22) Filed: Sep. 29, 2021

Related U.S. Application Data
(60) Provisional application No. 63/086,129, filed on Oct. 1, 2020.

(51) Int. Cl. H01P 5/16; H01Q 21/06; H01Q 3/36

(52) U.S. Cl. CPC H01P 5/16; H01Q 3/36; H01Q 21/06

(57) ABSTRACT

A power splitter-combiner with a combined port and a plurality of split ports has a first coupled inductor pair with each inductor connected to the combined port. A second coupled inductor pair is connected to one of the inductors of the first coupled inductor pair. A first inductor of the second coupled inductor pair is connected to a first split port, and a second one of the second coupled inductor pair is connected to a second split port. A third coupled inductor pair is connected to a second one of the inductors of the first coupled inductor pair. A first one of the inductors of the third coupled inductor pair is connected to a third split port, and a second one of the inductors of the third coupled inductor pair is connected to a fourth split port.

### CROSS-REFERENCE TO RELATED APPLICATIONS

This application relates to and claims the benefit of U.S. Provisional Application No. 63/086,129, filed Oct. 1, 2020 and entitled “POWER SPLITTER-COMBINER CIRCUITS IN 5G MM-WAVE BEAMFORMER ARCHITECTURES”, the disclosure of which is wholly incorporated by reference in its entirety herein.

### STATEMENT RE: FEDERALLY SPONSORED RESEARCH/DEVELOPMENT

Not Applicable

### BACKGROUND

### 1. Technical Field

The present disclosure related generally to radio frequency (RF) integrated circuit devices, and more particularly, to power splitter-combiner circuits in 5G millimeter wave (mm-Wave) beamformer architectures.

### 2. Related Art

Wireless communications systems find applications in numerous contexts involving information transfer over long and short distances alike, and a wide range of modalities tailored for each need have been developed. Chief among these systems with respect to popularity and deployment is the mobile or cellular phone. Generally, wireless communications utilize a radio frequency carrier signal that is modulated to represent data, and the modulation, transmission, receipt, and demodulation of the signal conform to a set of standards for coordination of the same. Many different mobile communication technologies or air interfaces exist, including GSM (Global System for Mobile Communications), EDGE (Enhanced Data rates for GSM Evolution), and UMTS (Universal Mobile Telecommunications System).

Various generations of these technologies exist and are deployed in phases, the latest being the 5G broadband cellular network system. 5G is characterized by significant improvements in data transfer speeds resulting from greater bandwidth that is possible because of higher operating frequencies compared to 4G and earlier standards. The air interfaces for 5G networks are comprised of two frequency bands, frequency range 1 (FR1), the operating frequency of which being below 6 GHz with a maximum channel bandwidth of 100 MHz, and frequency range 2 (FR2), the operating frequency of which being above 24 GHz with a channel bandwidth between 50 MHz and 400 MHz. The latter is commonly referred to as millimeter wave (mmWave) frequency range. Although the higher operating frequency bands, and mmWave/FR2 in particular, offer the highest data transfer speeds, the transmission distance of such signals may be limited. Furthermore, signals at this frequency range may be unable to penetrate solid obstacles. To overcome these limitations while accommodating more connected devices, various improvements in cell site and mobile device architectures have been developed.

One such improvement is the use of multiple antennas at both the transmission and reception ends, also referred to as MIMO (multiple input, multiple output), which is understood to increase capacity density and throughput. A series of antennas may be arranged in a single or multi-dimensional array, and further, may be employed for beamforming where radio frequency signals are shaped to point in a specified direction of the receiving device. A transmitter circuit feeds the signal to each of the antennas with the phase of the signal as radiated from each of the antennas being varied over the span of the array. The collective signal to the individual antennas may have a narrower beam width, and the direction of the transmitted beam may be adjusted based upon the constructive and destructive interferences from each antenna resulting from the phase shifts. Beamforming may be used in both transmission and reception, and the spatial reception sensitivity may likewise be adjusted.

A typical 5G mm-wave beamformer architecture includes a single RF signal input port and multiple antennas. The transmit signal at the defined carrier frequency is applied to the RF signal input port. The input signal is split into multiple chains using a splitter circuit, which may be a Wilkinson-type splitter. The split portions of the RF input signal are passed to individual transmit chains that may each comprise a phase shifter, a variable gain amplifier (VGA), and a power amplifier (PA), the output of which is connected to a single antenna element.

This interface circuit between the single RF signal input port and the antenna array is configured for receive operations as well, and includes individual receive chains, some of the components of which are shared with the transmit chain. The receive chain includes a low noise amplifier (LNA) and a separate variable gain amplifier (VGA), with the input to the low noise amplifier being connected to a single antenna element. There may be an intermediate RF switch, typically of the single pole, double throw type in which the pole terminal is connected to the antenna, the first throw terminal is connected to the transmit chain (e.g., the output of the power amplifier), and the second throw terminal is connected to the receive chain (e.g., the input of the low noise amplifier). The output of the receive chain variable gain amplifier is connected to a second RF switch, which is similarly of a single pole, double throw type in which the pole terminal is connected to the phase shifter, the first throw terminal is connected to the transmit chain (e.g., the input of the transmit chain variable gain amplifier), and the second throw terminal is connected to the receive chain (e.g., the output of the receive chain variable gain amplifier). The phase shifters are each connected to a combiner circuit, which has a single RF signal output port. The aforementioned splitter and such combiner circuit may be a single splitter-combiner.

The transmit chain and the receive chain may be comprised of separate and independent components aside from the shared intermediate RF switches and the splitter-combiner. However, in some cases, it is also possible for the transmit and receive chains to share certain components, for example, the phase shifter. In such implementations, one port of the phase shifter is connected to the splitter-combiner, and the other port is connected to the pole terminal of the second RF switch, and so the phase shifter may be part of separate transmit and receive chains, or a part of a common transmit-receive chain.

Current 5G mmWave phased array antenna solutions may utilize up to several hundred individual transmit and receive chains, as the total corresponds to the number of antenna elements in the array, which can be in the hundreds. Such larger configurations may be utilized for base stations, customer premise equipment (CPEs) and so forth. Each transmit chain and receive chain results in a corresponding increase in the semiconductor die area of the beamformer integrated circuit. Furthermore, each chain contributes to an undesirable increase in DC current drain from the bias supply, increase in switching speed between the transmit and receive chains, and increase in the number of control lines and associated serial peripheral interface (SPI) registers to control each of the circuits.

The Wilkinson-type splitter-combiner circuits are typically implemented as lengths of physical traces corresponding to the operating frequencies. Even at millimeter wave frequencies, the overall footprint of the splitter-combiner may be substantial, which directly results in the increased cost of the entire solution, whether implemented on the semiconductor die or in the laminate substrate. As a general matter, the large size of the Wilkinson splitter-combiner circuits are not well-suited for applications in which space is at a premium. Moreover, phased antenna array systems for base stations and customer premises equipment require a large number of splitter-combiners, so especially for such applications, size/footprint issues are exacerbated. The long lengths of the RF signal traces that define Wilkinson-type splitter-combiners are prone to increased insertion loss. The additional RF signal traces needed between the splitter-combiner ports and the rest of the circuit chains including the beam-forming RF integrated circuit, up-converter circuits, and the down-converter circuits further contribute to the insertion loss.

Existing devices may utilize an additional RF front end circuit to compensate for the aforementioned insertion loss and the split power loss. Such additional circuits may consume significant DC current, which results in associated higher temperatures and heat dissipation concerns. Accordingly, there is a need in the art for low-loss power splitter-combiners with a reduced size that may be positioned in close proximity to the antenna radiating elements and/or beam-forming RF integrated circuits. There is also a need in the art for active power splitter-combiners with gain, which can eliminate losses associated with splitting and allow for the elimination of RF front end circuits.

### BRIEF SUMMARY

The present disclosure is contemplates various embodiments of splitters, combiners, and splitter-combiners with improved noise figures and smaller footprints. These devices may be utilized in 5G mm-Wave beamformer applications, where the reduced size may allow placements in close proximity to antenna radiating elements and/or beamforming RF integrated circuits. The active power splitters and combiners may be configured to apply gain to the RF signals, thereby eliminating loss and possibly the elimination of an additional RF front end.

One embodiment of the present disclosure may be a passive power splitter-combiner with a combined port and a plurality of split ports. There may be a first coupled inductor pair with each such inductor being connected to the combined port. Furthermore, there may be a second coupled inductor pair with each such inductor being connected to a first one of the inductors of the first coupled inductor pair. A first one the inductors of the second coupled inductor pair may be connected to a first one of the plurality of split ports. A second one of the inductors of the second coupled inductor pair may be connected to a second one of the plurality of split ports. The passive power splitter-combiner may also include a third coupled inductor pair with each of the inductors being connected to a second one of the inductors of the first coupled inductor pair. A first one of the inductors of the third coupled inductor pair may be connected to a third one of the plurality of split ports. A second one of the inductors of the third coupled inductor pair may be connected to a fourth one of the plurality of split ports.

Another embodiment may be an active power splitter with a combined port and a plurality of split ports. The splitter may include a common main transistor that is connected to the combined port. There may also be an input matching network that is connected to the common main transistor and to the combined port. Further, there may be a plurality of cascode transistors that are each connected to a respective one of the plurality of split ports and to the common main transistor. The splitter may further incorporate a plurality of output matching networks that are each connected to a corresponding one of the plurality of cascode transistors. There may also be a bias supply that can be connected to each of the plurality of cascode transistors. A first one of the output matching networks and a second one of the output matching networks may each include an inductor that are coupled to each other. Furthermore, there may be a capacitor that is connected across the inductors of the first one of the output matching networks and the second one of the output matching networks. The capacitor may define a parallel resonance with the inductors.

Another embodiment may be an active power combiner with a plurality of split ports and a combined port. There may be a common cascode transistor with a gate, a drain connected to the combined port, and a source. The active power combiner may also include a plurality of main transistors that may each have a gate connected to a respective one of the plurality of split ports, a drain connected to the source of the common cascode transistor, and a source. There may also be a plurality of input matching circuits that are each connected to the gate of a respective one of the plurality of main transistors and the plurality of split ports. The active power combiner may also include a bias supply that is connected to the drain of the common cascode transistor

In still another embodiment of the present disclosure, there may be an active power splitter-combiner with a combined port and a plurality of split ports. The active power splitter-combiner may include a primary transistor that is connected to the combined port. There may also be a plurality of secondary transistors that are each connected to a corresponding one the split ports. The active power splitter-combiner may also incorporate a switching network that selectively connects the primary transistor and the plurality secondary transistors in a splitting mode with the primary transistor in a cascode configuration with the secondary transistors, and in a combining mode with the primary transistor and each of the secondary transistors in a common gate series connection configuration.

The present disclosure will be best understood accompanying by reference to the following detailed description when read in conjunction with the drawings.

### BRIEF DESCRIPTION OF THE DRAWINGS

These and other features and advantages of the various embodiments disclosed herein will be better understood with respect to the following description and drawings:

FIG. 1 is a schematic diagram of a first embodiment the present disclosure directed to a passive power splitter-combiner circuit;

FIG. 2 is a graph plotting the simulated scattering parameters (S-parameters) of the power splitter-combiner circuit shown in FIG. 1 in a 5G millimeter wave (mm-Wave) low band operating frequency;

FIG. 3 is a Smith chart plotting the simulated return losses of the power splitter-combiner circuit shown in FIG. 1 in the 5G mm-Wave low band operating frequency;

FIG. 4 is a graph plotting the simulated S-parameters of the power splitter-combiner circuit shown in FIG. 1 in a 5G mm-Wave high band operating frequency;

FIG. 5 is a Smith chart plotting the simulated return losses of the power splitter-combiner circuit shown in FIG. 1 in the 5G mm-Wave high band operating frequency;

FIG. 6 is a schematic diagram of a second embodiment of the present disclosure that is an active power splitter circuit;

FIG. 7 is a schematic diagram of a third embodiment of the present disclosure that is another variation of an active power splitter circuit;

FIG. 8 is schematic diagram of a fourth embodiment of the present disclosure that is an active power combiner circuit;

FIG. 9 is a schematic diagram of a fifth embodiment of the present disclosure that is an active power splitter-combiner circuit;

FIG. 10 is a schematic diagram of a sixth embodiment of the present disclosure that is a further variation of the active power splitter-combiner circuit with a reduced number of components and footprint relative to active power splitter-combiner circuit of the fifth embodiment of the present disclosure;

FIG. 11 is a schematic diagram showing an equivalent circuit of the active power-splitter combiner circuit of the sixth embodiment as would be operating in the combiner mode;

FIG. 12 is a schematic diagram of one variation of a seventh embodiment of the present disclosure that is a phased array beamformer architecture utilizing the power splitter-combiner circuit in accordance with various embodiments; and

FIG. 13 is a schematic diagram of another variation of the seventh embodiment of the present disclosure that is a phased array beam former architecture utilizing separate splitter and combiner circuits.

### DETAILED DESCRIPTION

The present disclosure encompasses various embodiments of splitters, combiners, and splitter-combiners, one possible application of which is in 5G millimeter wave (mm-Wave) phased antenna array beamformers. These circuits are contemplated to reduce overall noise figure and enhance gain in receive mode, as well as increase gain in transmit mode while maintaining a small footprint with respect to the entire beamformer system.

The detailed description set forth below in connection with the appended drawings is intended as a description of the several presently contemplated embodiments of the circuits and is not intended to represent the only form in which the disclosed invention may be developed or utilized. The description sets forth the functions and features in connection with the illustrated embodiments. It is to be understood, however, that the same or equivalent functions may be accomplished by different embodiments that are also intended to be encompassed within the scope of the present disclosure. It is further understood that the use of relational terms such as first and second and the like are used solely to distinguish one from another entity without necessarily requiring or implying any actual such relationship or order between such entities.

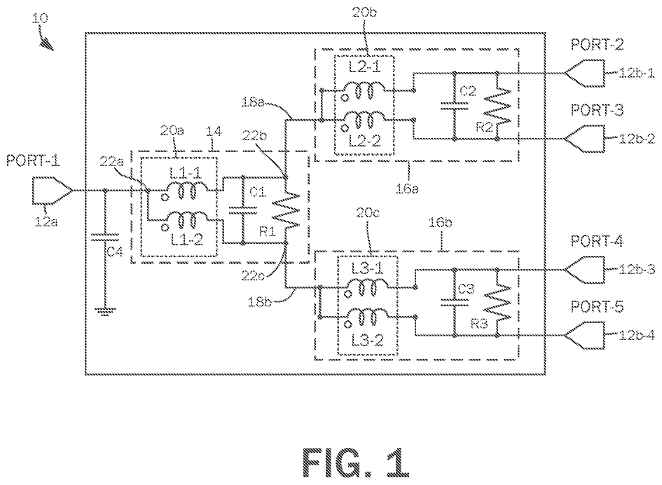

The schematic diagram of FIG. 1 illustrates a first embodiment of the present disclosure, which in accordance therewith, is a passive power splitter-combiner 10. There is combined port 12a that may also be referenced as port-1, along with multiple split ports 12b-1 (port-2), 12b-2 (port-3), 12b-3 (port-4), and 12b-4 (port-5). As is the case with any splitter-combiner, the passive power splitter-combiner 10 is a bi-directional device in which an input signal applied to the combined port 12a is split to the multiple split ports 12b-1, 12b-2, 12b-3, and 12b-4, while multiple input signals applied to the split ports 12b-1, 12b-2, 12b-3 and 12b-4 are combined to the single combined port 12a.

In the illustrated embodiment, the passive power splitter-combiner 10 is generally defined by a main circuit segment 14 that is connected to the combined port 12a, and two circuit branches 16, including a first circuit branch 16a and a second circuit branch 16b. The first circuit branch 16a is connected to the main circuit segment 14 with a first connection 18a, while the second circuit branch 16b is connected to the main circuit segment 14 with a second connection 18b. The first circuit branch 16a, in turn, is connected to the split port 12b-1 and the split port 12b-2, and the second circuit branch 16b is connected to the split port 12b-3 and the split port 12b-4.

The main circuit segment 14 includes a first coupled inductor pair 20a of inductor L1-1 and inductor L1-2, both of which are connected to the combined port 12a. Connected across the first coupled inductor pair 20a is a capacitor C1 and a resistor R1. The first circuit branch 16a likewise includes a second coupled inductor pair of inductor L2-1 and inductor L2-2, both of which are connected to the first circuit branch 16a and specifically the inductor L1-1 of the first coupled inductor pair 20a. Connected across the second inductor pair 20b is a capacitor C2 and a resistor R2, with the inductor L2-1 being connected to the split port 12b-1 and the inductor L2-2 being connected to the split port 12b-2. Along these lines, the second circuit branch 16b includes a third coupled inductor pair of inductor L3-1 and inductor L3-2, both of which are connected to the main circuit segment 14 and the inductor L1-2 of the first coupled inductor pair 20a. Connected across the third inductor pair 20c is a capacitor C3 and a resistor R3, with the inductor L3-1 being connected to the split port 12b-3 and the inductor L3-2 being connected to the split port 12b-4.

The inductance value of one coupled chain is equal to that of another coupled chain, which results in equal power splitting at the electrically separate nodes of the coupled inductors between which the capacitor and resistor are connected. For example, the inductor L1-1 and the inductor L1-2 have the same inductance, and the power of a signal applied to a node 22a that is electrically contiguous with the inductor L1-1 and the inductor L1-2 is split equally between a second node 22b of the junction between the other connection of the inductor L1-1, the capacitor C1, and the resistor R1, and a third node 22c of the junction between the other connection of the inductor L1-2, the capacitor C1, and the resistor R1. The value of the resistors R1 and C1 are understood to be chosen for the highest isolation between the split nodes, e.g., the nodes 22b and 22c, in the case of the main circuit segment 14. The capacitor is in parallel resonance with coupled inductor pair. The resistance value may be selected to achieve a good return loss at each port, for example, less than −10 dB, as well as a minimum insertion loss across the combined and split ports. Along these lines, the inductance value of each of the coupled inductor chains is selected to achieve minimal insertion loss, and the coupling factor between a given one of the coupled inductors coils is selected to minimize its footprint on the semiconductor die on which the passive power splitter-combiner 10 is implemented, typically with a k of 0.5 to 0.9. The same considerations understood to be applicable to the first circuit branch 16a and the components therein, e.g., the inductors L2-1, L2-2, the capacitor C2, and the resistor R2, as well as the second circuit branch 16b and the components therein, e.g., the inductors L3-1, L3-2, the capacitor C3, and the resistor R3.

Connected to the combined port 12a and the node 22a of the main circuit segment 14 is a matching capacitor C4. According to an embodiment, the value of the matching capacitor C4 is selected to achieve a good return loss (e.g., less than −10 dB) at all of the ports 12. Furthermore, the impedance of each of the ports 12 is 50 Ohm.

Thus, an RF signal that is applied to the combined port 12a is understood to be split evenly across the four split ports 12b-1, 12b-2, 12b-3, and 12b-4 with equal amplitude and phase in accordance with the illustrated embodiment of the passive power splitter-combiner 10. That is, a splitter mode operation is contemplated. Ideally, the power level at each of the split ports is 6 dB lower than that of the power applied to the combined port, though in a typical implementation, each of the split port power is understood to be reduced by the insertion loss in each chain that is attributable to resistive losses in the components therein, as well as mismatch loss. Furthermore, the passive power splitter-combiner 10 may also be operated in a combiner mode, in which RF signals applied to the split ports 12b are constructively combined at the combined port 12a.

In the embodiments of the passive power splitter-combiner 10, the main circuit segment 14, that is, the first coupled inductor pair 20a, splits power but not to 50 Ohm impedance at the split ports 22b and 22c. The first circuit branch 16a and the second circuit branch 16b further equally splits power, but the input impedance at nodes 18a and 18b thereof are also not 50 Ohm but are rather the impedance of the outputs of the main circuit segment 14 at the nodes 22b, 22c.

The operation of the passive power splitter-combiner 10 in accordance with the illustrated embodiment is understood to be similar to that of a conventional Wilkinson-type splitter-combiner, though the total footprint may be significantly reduced in comparison thereto. Furthermore, the split ports of conventional splitter-combiners are understood to have impedances that are half that of the combined port, so additional matching circuitry that occupy additional die real estate, along with associated insertion losses, become necessary. It is expressly contemplated that the passive power splitter-combiner 10 may be implemented with various semiconductor technologies, as well as with laminate and low-temperature co-fired ceramic (LTCC) substrates.

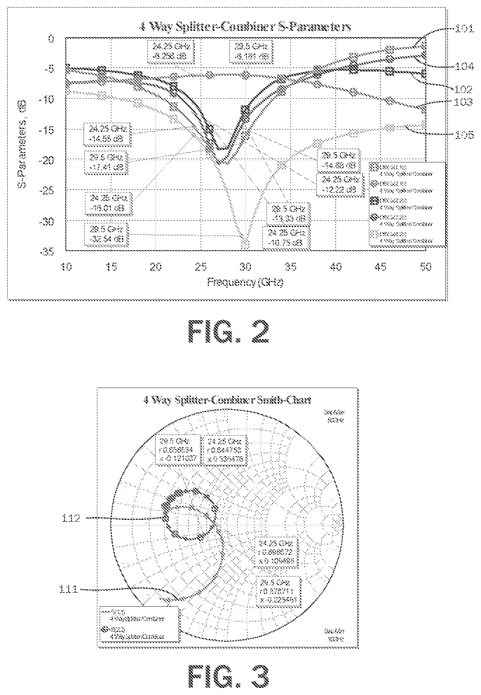

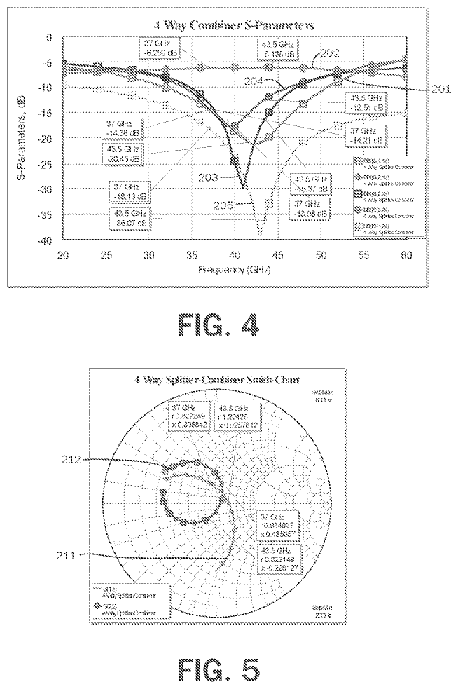

Referring now to the graphs and Smith charts of FIGS. 2, 3, 4, and 5, the simulated performance of the passive power splitter-combiner 10 will now be considered, with FIGS. 2 and 3 showing the simulated performance for 5G mm-Wave low band, that is, 24.25 GHz to 29.5 GHz, and FIGS. 4 and 5 showing the simulated performance for 5G mm-Wave high band, or 37 GHz to 43.5 GHz. In further detail, FIG. 2 plots the 5G mm-Wave low band simulated scattering parameters (S-parameters) of the passive power splitter-combiner 10, with a first plot 101 showing the reflection coefficient/return loss S11 at the combined port 12a, and a second plot 102 showing the reflection coefficient S22 at an exemplary split port 12b-1. A third plot 103 shows the insertion loss S21 between ports 12a and 12b-1. A fourth plot 104 show the isolation between an exemplary split port 12b-1 and another split port 12b-2, which are ports that are connected to the same circuit branch 16a, while a fifth plot 105 shows the isolation between an exemplary split port 12b-1 and another split port 12b-3, which are ports that are connected to different circuit branches 16a, 16b. The Smith chart of FIG. 3 also includes a first plot 111 of the simulated reflection coefficient/return loss S11 of the combined port 12a and a second plot 112 of the simulated reflection coefficient/return loss S22 of an exemplary one of the split ports 12b, e.g, the split port 12b-1. As can be seen from the foregoing, the typical insertion loss is less than 0.26 dB, and the typical isolation between the split ports 12b is less than −10 dB. Moreover, the typical return loss at a given one of the ports 12 is likewise less than −10 dB.

These simulations were based on specific component values as detailed below. In particular, each of the inductors of the coupled inductor pairs 20 utilized in the passive power splitter-combiner 10, that is inductors L1-1, L1-2, L2-1, L2-2, L3-1, and L3-2, is understood to have an inductance value of 100 pico Henries. Each of these inductors are also understood to have a corresponding resistive loss of 300 milliohm, and the coupling coefficient k between the coils of each coupled inductor pair were set to 0.5. The capacitance value of the capacitor C1 in the main circuit segment 14, which is the first coupled coil resonating capacitance, was set to 353 femtofarad, and the first coupled inductor/coil matching resistance R1 was set to 50 Ohm. The capacitance value of the capacitor C2 in the first circuit branch 16a, and the capacitor C3 in the second circuit branch 16b, which are the second and third coupled inductor/coil resonating capacitance, were set to 338 femtofarad, and the second and third coupled coil inductor/coil matching resistance R2, R3 was set to 80 Ohm. Lastly, the capacitance value of the matching capacitor C4 was set to 218 femtofarad.

FIG. 4 plots the 5G mm-Wave high band simulated S-parameters of the passive power splitter-combiner 10, with a first plot 201 showing the reflection coefficient/return loss S11 at the combined port 12a, and a second plot 202 showing the reflection coefficient S22 at an exemplary split port 12b-1. A third plot 203 shows the insertion loss S21 between ports 12a and 12b-1. A fourth plot 204 show the isolation between an exemplary split port 12b-1 and another split port 12b-2 that are ports that are connected to the same circuit branch 16a, while a fifth plot 205 shows the isolation between an exemplary split port 12b-1 and another split port 12b-3 that are ports that are connected to different circuit branches 16a, 16b. The Smith chart of FIG. 5 shows a first plot 211 of the simulated reflection coefficient/return loss S11 of the combined port 12a and a second plot 212 of the simulated reflection coefficient/return loss S22 of an exemplary one of the split ports 12b, e.g., the split port 12b-1. The typical insertion loss is again less than 0.26 dB, and the typical isolation between the split ports 12b is less than −10 dB. The typical return loss at a given one of the ports 12 is also less than −10 dB.

These simulations were based on specific component values as detailed below. In particular, each of the inductors of the coupled inductor pairs 20 utilized in the passive power splitter-combiner 10, that is inductors L1-1, L1-2, L2-1, L2-2, L3-1, and L3-2, is understood to have an inductance value of 80 pico Henries. Each of these inductors are also understood to have a corresponding resistive loss of 300 milliohm, and the coupling coefficient k between the coils of each coupled inductor pair were set to 0.5. The capacitance value of the capacitor C1 in the main circuit segment 14, which is the first coupled coil resonating capacitance, was set to 196 femtofarad, and the first coupled inductor/coil matching resistance R1 was set to 70 Ohm. The capacitance value of the capacitor C2 in the first circuit branch 16a, and the capacitor C3 in the second circuit branch 16b, which are the second and third coupled inductor/coil resonating capacitance, were set to 200 femtofarad, and the second and third coupled coil inductor/coil matching resistance R2, R3 was set to 100 Ohm. Lastly, the capacitance value of the matching capacitor C4 was set to 116 femtofarad.

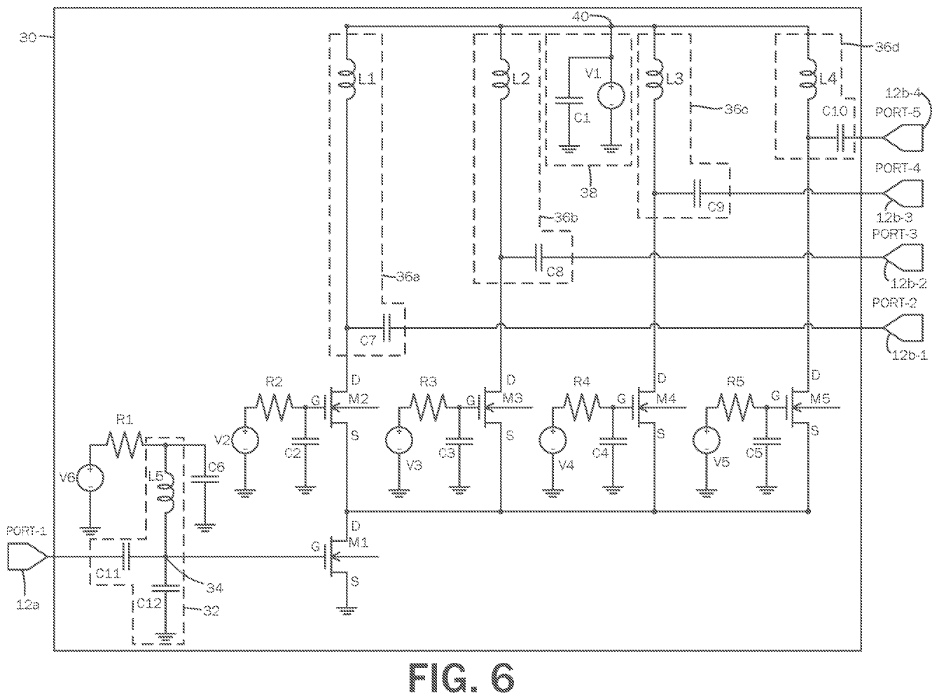

The schematic diagram of FIG. 6 shows a second embodiment of the present disclosure, an active power splitter 30. As will be described in further detail below, this circuit is based upon a common main transistor M1 and multiple cascode transistors M2, M3, M4, and M5. Like the passive power splitter-combiner 10 discussed above, the active power splitter 30 includes the combined port 12a (also referenced as port-1), and multiple split ports 12b-1 (port-2), 12b-2 (port-3), 12b-3 (port-4), and 12b-4 (port-5). Each of the split ports 12b are understood to have an impedance of 50 Ohm according to various embodiments of the present disclosure.

Connected to the combined port 12a is an input matching network 32 that includes a capacitor C11, a capacitor C12, and an inductor L5. The common main transistor M1, and specifically the gate thereof, is connected to a common node 34 to which the capacitors C11 and C12, and the inductor L5 are connected. The input matching network 32 is understood to match to the 50 Ohm impedance of the combined port 12a. Although a specific implementation of the input matching network 32 is provided, this is understood to be by way of example only. Any other suitable configuration of the input matching network 32 may be substituted without departing from the present disclosure.

The cascode transistors M2, M3, M4, and M5 may each be designated for a specific split port 12b-1, 12b-2, 12b-3, and 12b-4, respectively, and are in a cascode configuration with the common main transistor M1. That is, the source of each of the cascode transistors M2, M3, M4, and M5 are connected to the drain of the common main transistor M1. Each of the cascode transistors are connected to an output matching network 36. The first cascode transistor M2, and specifically the drain thereof, is connected to a first output matching network 36a that includes the inductor L1 and the capacitor C7. The first split port 12b-1 is connected to the capacitor C7. The drain of the second cascode transistor M3 is connected to a second output matching network 36b that includes the inductor L2 and the capacitor C8, with the second split port 12b-2 being connected to the capacitor C8. The drain of the third cascode transistor M4 is connected to a third output matching network 36c that includes the inductor L3 and the capacitor C9, with the third split port 12b-3 being connected to the capacitor C9. Lastly, the drain of the fourth cascode transistor M5 is connected to a fourth output matching network 36d including the inductor L4 and the capacitor C10, which in turn is connected to the fourth split port 12b-4. The configuration of the output matching networks 36 is presented by way of example only and not of limitation, and any other suitable matching circuit configuration may be substituted without departing from the scope of the present disclosure.

The cascode transistors M2, M3, M4, and M5 are each connected to a bias supply circuit 38. Specifically, the output matching networks 36 are each connected to the bias supply circuit 38 at a common bias supply node 40, and so the drains of the cascode transistors M2, M3, M4, and M5 are connected to the bias supply circuit 38 via a respective one of the inductors L1, L2, L3, and L4. The bias supply circuit 38 may include a voltage source V1, along with a bypass capacitor C1 that provides high isolation between the signals at the split ports 12b. The contemplated isolation is understood to be greater than 10 dB.

The common main transistor M1 is provided with a constant voltage from voltage source V6, which is connected to the gate thereof through the resistor R1. A capacitor C6 connected to the voltage source V6 is understood to serve a bypass purpose. Similarly, the gate of each of the cascode transistors M2, M3, M4, and M5 are connected to respective voltage sources V2, V3, V4, and V5 over the resistors R2, R3, R4, and R5. These resistors may be configured with large resistance values, for example, greater than 1 kOhm. Additionally, there are capacitors C2, C3, C4, and C5 that are each connected to the gate of the cascode transistors. These capacitors are understood to serve impedance matching purposes for proper operation in the cascode configuration. The volage sources V2, V3, V4, and V5 are depicted as such, but may be substituted with current sources when accompanied by appropriate mirroring circuitry.

The functionality of the active power splitter 30 is based in part on the cascode configuration of the common main transistor M1 and the cascode transistors M2, M3, M4, and M5. In this regard, the bias supply V6 is set to a high state and applies a predefined voltage to the gate of the common main transistor M1. The operation of the common main transistor M1 is thus enabled, providing a predefined quiescent current as the main transistor in a cascode configuration. The bias supply voltages V2, V3, V4, and V5 are also set to high states/enabled concurrently, with the voltage therefrom being applied to the gates of the cascode transistors M2, M3, M4, and M5, respectively. The cascode transistors are thus enabled, and a predefined bias point is provided for a proper cascode operation.

With the common main transistor M1 and all of the cascode transistors M2, M3, M4, and M5 enabled, an RF signal applied to the combined port 12a is amplified by the common main transistor M1 and split to four equal signals at the split ports 12b-1, 12b-2, 12b-3, and 12b-4. On the other hand, if all of the transistors M1-M5 are disabled, the DC current is set to zero and there is no RF signal gain. The cascode transistors M2-M5 may be selectively enabled according to another embodiment of the present disclosure. In such case, the splitting may be operational only with respect to those cascode transistors that are activated. Accordingly, it is possible to split the power by three, by two, or even operate as a single stage amplification chain if desired. The fewer number of cascode transistors M2-M5 that are enabled, the lower the quiescent current. To the extent additional splitting is desired, additional cascode transistors may be incorporated. The four cascode transistor/split port 12b configuration described above may be suitable for transmitter chains in 5G mm-Wave beam former applications where there are four distinct RF signal channels.

The size of the transistors, the bias points, and the component values may be selected to achieve a particular gain at the split ports 12b when the RF input signal is applied to the combined port 12a. The gain may be set to be between 0 dB up to 6 dB, though this range is presented by way of example only and not of limitation. It will be recognized that proper layout may be necessary to ensure that each of the output signals from the split ports 12b have the same phase and amplitude, such layout options being within the purview of those having ordinary skill in the art.

As will be appreciated, the active power splitter 30 of the present disclosure may have a small footprint when implemented on a semiconductor die, regardless of the fabrication technology. Although the present disclosure illustrates the embodiments utilizing n-channel metal oxide semiconductor (NMOS) transistors with gates, drains, and sources, bipolar transistors with bases, collectors, and emitters may be substituted while retaining the same functionality discussed above.

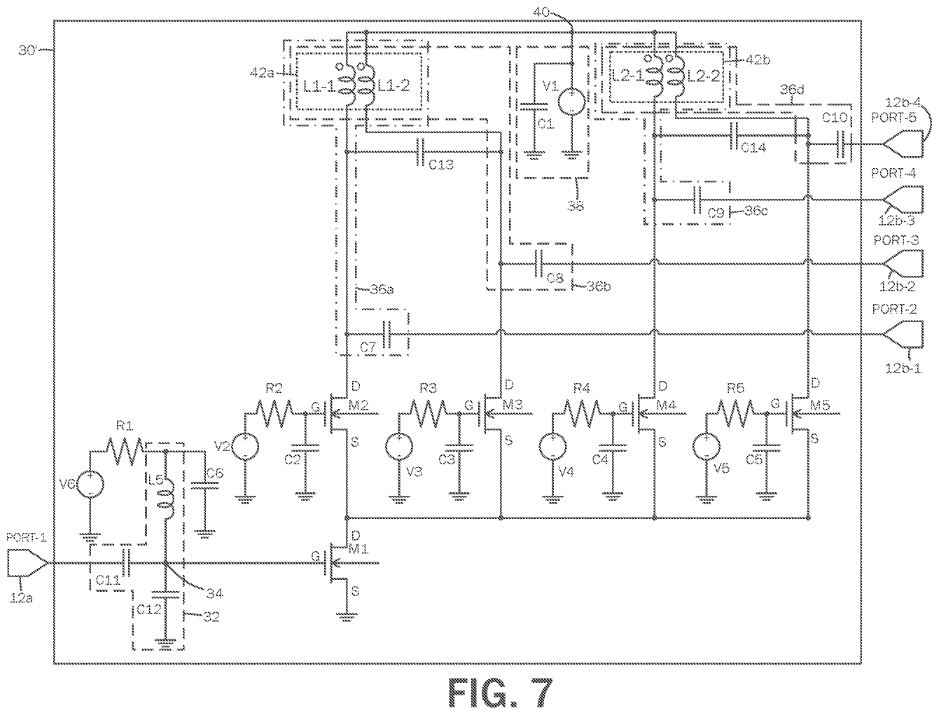

The schematic diagram of FIG. 7 shows a third embodiment of an active power splitter 30′, which is understood to be a variation of the second embodiment. This variation is also based upon a common main transistor M1 and multiple cascode transistors M2, M3, M4, and M5. Again, the active power splitter 30′ has the combined port 12a (port-1), and multiple split ports 12b-1 (port-2), 12b-2 (port-3), 12b-3 (port-4), and 12b-4 (port-5). Each of the split ports 12b are understood to have an impedance of 50 Ohm.

Connected to the combined port 12a is the same input matching network 32 that includes the capacitor C11, the capacitor C12, and the inductor L5. The common main transistor M1, and specifically the gate thereof, is connected to the common node 34 to which the capacitors C11 and C12, and the inductor L5 are connected. The input matching network 32 is understood to match to the 50 Ohm impedance of the combined port 12a.

The cascode transistors M2, M3, M4, and M5 may each be designated for a specific split port 12b-1, 12b-2, 12b-3, and 12b-4, respectively, and are in a cascode configuration with the common main transistor M1. Again, the source of each of the cascode transistors M2, M3, M4, and M5 are connected to the drain of the common main transistor M1. Furthermore, each of the cascode transistors are connected to the output matching network 36 like the first variation described above, though the specific configuration of the same differs. Instead of individual inductors, coupled inductor pairs are utilized.

There is a first coupled inductor pair 42a with a first inductor L1-1 and a second inductor L1-2. The drain of the first cascode transistor M2 is connected to the inductor L1-1, which is also inductively coupled to the second inductor L1-2. The first coupled inductor pair 42a is understood to be part of the first output matching network 36a that additionally includes the capacitor C7, which in turn is connected to the first split port 12b-1. The drain of the second cascode transistor M3 is connected to the second inductor L1-2 that is inductively coupled to the first inductor L1-1. In this regard, the first coupled inductor pair 42a is also a part of the second output matching network 36b that additional includes the capacitor C8, which in turn is connected to the second split port 12b-2. A parallel resonance capacitor C13 is connected across the first inductor L1-1 and the second inductor L1-2 of the first coupled inductor pair 42a and is understood to define a parallel resonance that improves isolation between the first split port 12b-1 and the second split port 12b-2.

The variation of the active power splitter 30′ further includes a second coupled inductor pair 42b with a first inductor L2-1 and a second inductor L2-2. The drain of the third cascode transistor M4 is connected to the first inductor L2-1, which is also inductively coupled to the second inductor L2-2. The second coupled inductor pair 42b is thus a part of the third output matching network 36c that additionally includes the capacitor C9, which in turn is connected to the third split port 12b-3. The drain of the fourth cascode transistor M5 is connected to the second inductor L2-2 that is inductively coupled to the first inductor L2-1. The first coupled inductor pair 42a is therefore also a part of the fourth output matching network 36d that additional includes the capacitor C10, which in turn is connected to the fourth split port 12b-4. A parallel resonance capacitor C14 is connected across the first inductor L2-1 and the second inductor L2-2 of the second coupled inductor pair 42b and is understood to define a parallel resonance that improves isolation between the third split port 12b-3 and the fourth split port 12b-4.

The other end of the coupled inductor pairs 42, and hence the output matching networks 36 are connected to the bias supply circuit 38. Accordingly, the drains of the cascode transistors M2, M3, M4, and M5 are connected to the bias supply circuit 38 via a respective one of the inductors L1-1, L1-2, L2-1, and L2-2. The bias supply circuit 38 includes the voltage source V1 and the bypass capacitor C1 that provides high isolation between the signals at the split ports 12b.

The remaining segments of the active power splitter 30′ are identical to the first variation of the active power splitter 30 described above. Specifically, the common main transistor M1 is provided with the constant voltage from voltage source V6, which is connected to its gate through the resistor R1. Similarly, the gate of each of the cascode transistors M2, M3, M4, and M5 are connected to respective voltage sources V2, V3, V4, and V5 over the resistors R2, R3, R4, and R5. There are the capacitors C2, C3, C4, and C5 that are each connected to the gate of the cascode transistors. Accordingly, the functionality of the active power splitter 30′ is the same and will not be repeated for the sake of brevity. The individual inductors of the coupled inductor pairs 42 may be positioned in close proximity to each other to minimize its footprint on a semiconductor die, though it is expressly contemplated for one of the coupled inductor pairs (e.g., 42a) is physically separated from another one of the coupled inductor pairs (e.g., 42b) so that coupling between any one of the individual inductors of different pairs can be minimized.

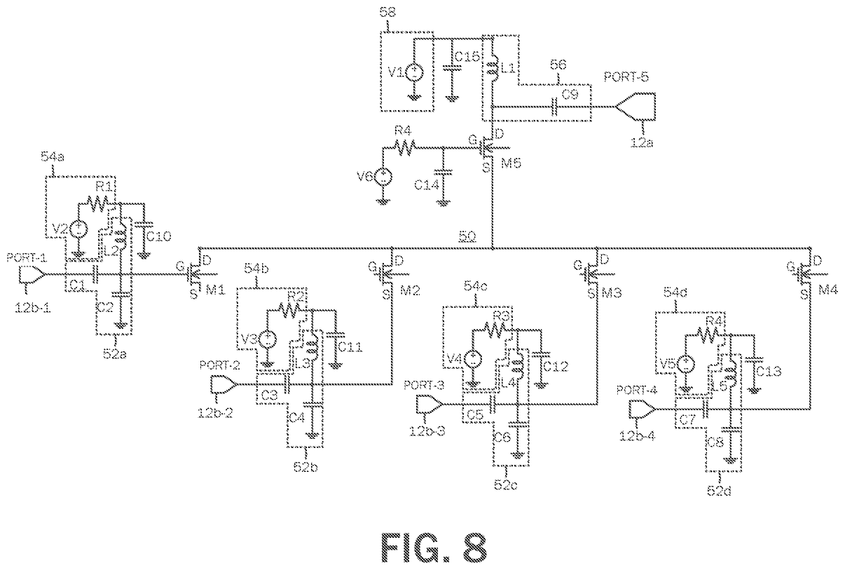

The schematic diagram of FIG. 8 shows a fourth embodiment of the present disclosure, which is an active power combiner 50. The active power combiner 50 has the combined port 12a (port-5), and multiple split ports 12b-1 (port-1), 12b-2 (port-2), 12b-3 (port-3), and 12b-4 (port-4). The combined port 12a as well as each of the split ports 12b are understood to have an impedance of 50 Ohm.

The active power combiner 50 incorporates a common cascode transistor M5, together with multiple main transistors M1, M2, M3, and M4 that are connected to and associated with the split ports 12b-1, 12b-2, 12b-3, and 12b-4. Accordingly, the common transistor serves as the cascode transistor, while the separate transistors for each split port serve as the main transistors in a cascode configuration, which is understood to be the opposite of the active power splitters 30, 30′ described above.

The first split port 12b-1 is connected to the gate of a first main transistor M1 via a first input matching network 52a comprised of a capacitor C1, a capacitor C2, and an inductor L2. A first bias supply source 54a comprised of the voltage source V2 through the resistor R1 is also connected to the gate of the first main transistor M1. A capacitor C10 is provided for bypass purposes while a constant voltage is applied to the gate of the first main transistor M1. The second split port 12b-2 is connected to the gate of a second main transistor M2 via a second input matching network 52b that is comprised of a capacitor C3, a capacitor C4, and an inductor L3. A second bias supply source 54b comprised of the voltage source V3 through the resistor R2 is connected to the gate of the second main transistor M2, and there is a bypass capacitor C11. The third split port 12b-3 is connected to the gate of a third main transistor M3 via a third input matching network 52c comprised of a capacitor C5, a capacitor C6, and an inductor L4. A third bias supply source 54c comprised of the voltage source V4 through the resistor R3 is connected to the gate of the third main transistor M3, along with a bypass capacitor C12. Lastly, the fourth split port 12b-4 is connected to the gate of a fourth main transistor M4 via a fourth input matching network 52d comprised of a capacitor C7, a capacitor C8, and an inductor L5. A fourth bias supply source 54d comprised of the voltage source V5 through the resistor R4 is connected to the gate of the third main transistor M4, along with a bypass capacitor C13.

The input matching networks 52a-52d are understood impedance match the main transistors M1, M2, M3, and M4 to the respective split ports 12b-1, 12b-2, 12b-3, and 12b-4, respectively. As indicated above the split ports 12b are configured to define a 50 Ohm impedance. Though a specific topology of the input matching networks 52 is presented, any other suitable configuration may be substituted.

The drains of each of the main transistors M1, M2, M3, and M4 are connected to a source of the common cascode transistor M5. An output matching network 56 is connected to the drain of the common cascode transistor M5 and is comprised of the inductor L1 and the capacitor C9. The output matching network 56 is in turn connected to the combined port 12a, and though a specific topology is presented, it will be appreciated that any other suitable configuration may be substituted without departing from the scope of the present disclosure. A cascode bias supply 58/V1 is connected to the drain of the common cascode transistor M5 via the inductor L1, with a bypass capacitor C15 being connected to the cascode bias supply V1. Also connected to the gate of the common cascode transistor M5 is a voltage source V6 that is connected through the resistor R4, which is understood to be a large value of greater than 1 kilo-Ohm. The capacitor C14 connected to the gate of the common cascode transistor M5 is understood to be for matching purposes and to ensure proper cascode operation. The volage sources V2, V3, V4, V5, and V6 are depicted as such, but may be substituted with current sources when accompanied by appropriate mirroring circuitry.

As indicated above, the functionality of the active power combiner 50 is based in part on the cascode configuration of the main transistors M1, M2, M3, and M4, and the common cascode transistor M5. Each of the bias supply sources 54a-54d (V2, V3, V4, and V5) are set to a high state, thereby applying the voltage to the gates of the main transistors M1-M4. The operation of the main transistors M1-M4 is thus enabled, each providing a quiescent current as the main transistors in a cascode configuration. Furthermore, the bias supply V6 is also set to a high state and applies a predefined voltage to the gate of the common cascode transistor M5. The cascode transistor M5 is thus enabled, and a predefined bias point is provided for a proper cascode operation.

With the common main transistors M1, M2, M3, and M4, and the common cascode transistor M5 enabled, an RF signal applied to the split ports 12b-1, 12b-2, 12b-3, and 12b-4 are constructively summed at the combined port 12a via the cascode transistor M5. If all of the transistors M1-M5 are disabled, the DC current is set to zero and there is no RF signal gain. The main transistors M1-M4 may be selectively enabled according to another embodiment of the present disclosure. In such case, the combining may be operational only with respect to those main transistors that are activated. Accordingly, it is possible to split the power by three, by two, or even operate as a single stage amplification chain if desired. The fewer number of main transistors M1-M4 that are enabled, the lower the quiescent current. Further, to the extent any of the chains in the active power combiner 50 is not required to pass an RF signal, it is preferable to disable such chains so as to not add additional noise power at the combined port 12a. To the extent additional combining is desired, additional main transistors may be incorporated. The four main transistor/split port 12b configuration described above may be suitable for receive chains in 5G mm-Wave beam former applications where there are four distinct RF signal channels.

The size of the transistors, the bias points, and the component values may be selected to achieve a particular gain at the combined port 12a when the RF input signal is applied to the split ports 12b. The gain may be set to be between 0 dB up to 6 dB, though this range is presented by way of example only and not of limitation. It will be recognized that proper layout may be necessary to ensure that the input signals to the split ports 12b are set to result in the same phase and amplitude, such layout options being within the purview of those having ordinary skill in the art.

The active power combiner 50 of the present disclosure may have a small footprint when implemented on a semiconductor die, regardless of the fabrication technology. Although the present disclosure illustrates the embodiments utilizing n-channel metal oxide semiconductor (NMOS) transistors with gates, drains, and sources, bipolar transistors with bases, collectors, and emitters may be substituted while retaining the same functionality discussed above.

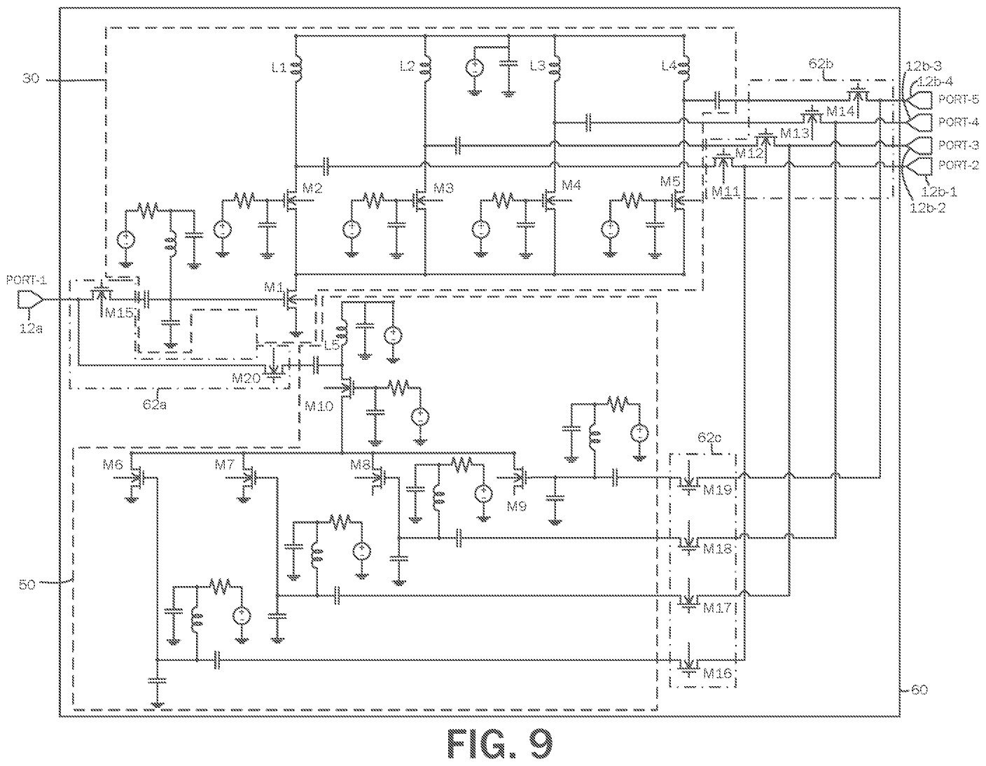

The aforementioned active power splitter 30 and the active power combiner 50 can be integrated into a single active power splitter-combiner 60 as shown in the schematic diagram of FIG. 9 in accordance with a fifth embodiment of the present disclosure. The active power splitter-combiner 60 likewise incorporates the combined port 12a (port-1), and multiple split ports 12b-1 (port-2), 12b-2 (port-3), 12b-3 (port-4), and 12b-4 (port-5). As with the active power splitter 30, the combined port 12a as well as each of the split ports 12b are understood to have an impedance of 50 Ohm.

The portion of the active power splitter-combiner 60 that constitutes the active power splitter 30 includes the common main transistor M1 that is connected to multiple cascode transistors M2, M3, M4, and M5 corresponding and selectively connected to the split ports 12b-1, 12b-2, 12b-3, and 12b-4, respectively. The portion of the active power splitter-combiner 60 that constitutes the active power combiner 50 includes the main transistors M6, M7, M7, and M8, which correspond and are selectively connected to the split ports 12b-1, 12b-2, 12b-3, and 12b-4, respectively. Additionally, the active power combiner 50 segment includes the common cascode transistor M10.

To switch between splitting operation and combining operation, the active power splitter-combiner 60 incorporates three switching circuits: a first switching circuit 62a connected to the combined port 12a, and two separate ones for the split ports 12b including a second switching circuit 62b for the active power splitter 30, and a third switching circuit 62c for the active power combiner 50.

In further detail the first switching circuit 62a is comprised of the transistor M15 and the transistor M20. The transistor M15 is connected to the combined port 12a as well as the gate of the common main transistor M1, which generally corresponds to the input of the active power splitter 30. As described above, there are bias supply sources and input matching circuits, but the details thereof will not be discussed for the sake of brevity. The transistor M20 is also connected to the combined port 12a, and the gate of the common cascode transistor M10, which generally corresponds to the output of the active power combiner 50. The transistor M15 and the transistor M20 may be selectively and exclusively activated for establishing an active connection of either the active power splitter 30 (with only the transistor M15 activated) or the active power combiner 50 (with only the transistor M20 activated) to the combined port 12a.

The second switching circuit 62b is comprised of transistors M11, M12, M13, and M14 that are connected to the cascode transistors M2, M3, M4, and M5, respectively. Again, the cascode transistors are understood to be connected to the split ports 12b over respective output matching networks, but because such features and their functionalities will not be repeated for the sake of brevity.

The third switching circuit 62c is comprised of transistors M16, M17, M18, and M19 that are connected to the gates of the main transistors M6, M7, M8, and M8, respectively. The main transistors are connected to the split ports 12b over corresponding input matching networks, but having considered these features earlier, the details thereof will not be repeated.

Like with the first switching circuit 62a, the set of transistors M11, M12, M13, and M14 constituting the second switching circuit 62b and the set of transistors M16, M17, M18, and M19 constituting the third switching circuit 62c may be exclusively activated to enable and connect to the split ports 12b the active power splitter 30 or the active power combiner 50. When the second switching circuit 62b is activated and the third switching circuit 62c is deactivated, the RF input signal at the combined port 12a may be amplified by the cascode circuit comprising the main transistor M1 and each of the cascode transistors M2, M3, M4, and M5. The transistor M15 of the first switching circuit 62a is activated while the transistor M20 is deactivated so that the RF input signal can be passed to the cascode circuit of the active power splitter 30. The signal is split and passed to the first split port 12b-1, the second split port 12b-2, the third split port 12b-3, and the fourth split port over the activated transistors M11, M12, M13, and M14, respectively.

When the second switching circuit 62b is deactivated and the third switching circuit 62c is activated, the RF input signals at the split ports 12b are passed to the cascode circuit over the transistors M16, M17, M18, and M19, and amplified by the main transistors M6, M7, M8, and M9 together with the common cascode transistor M10. The amplified and combined RF signal is then passed to the combined port 12a over the transistor M20 of the first switching circuit 62a.

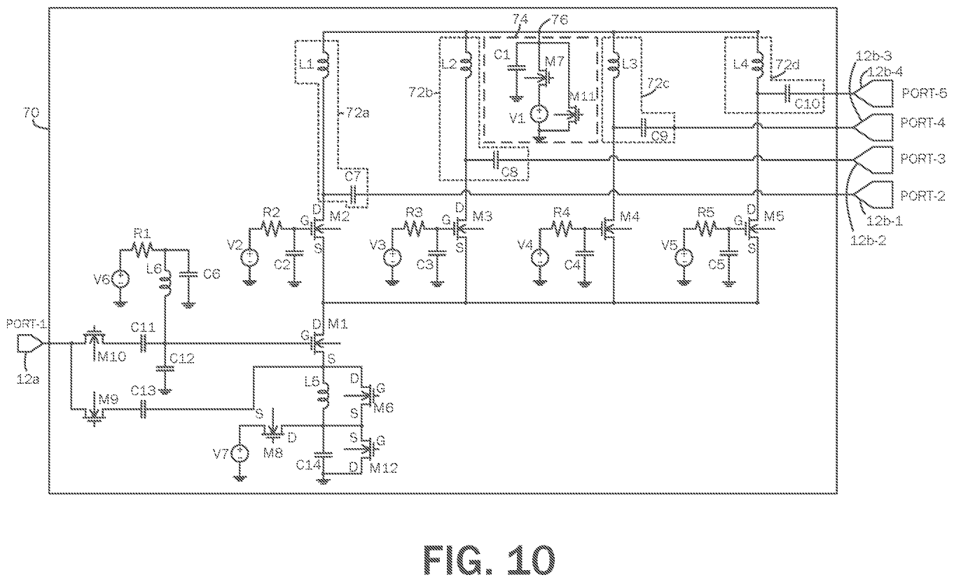

FIG. 10 illustrates a sixth embodiment of the present disclosure, which is a streamlined variation of an active power splitter-combiner 70 in which the components can be used for either splitting operation or combining operation, depending on how the interconnections between such components are established and configured. This active power splitter-combiner 70 is contemplated to utilize a fewer number of components relative to the fifth embodiment, the active power splitter-combiner 60 illustrated in FIG. 9, and hence have a smaller footprint on the semiconductor die. The same functionality and performance is maintained, however.

The active power splitter-combiner 70 includes the combined port 12a (port-1), and multiple split ports 12b-1 (port-2), 12b-2 (port-3), 12b-3 (port-4), and 12b-4 (port-5). As with the active power splitter 30, the combined port 12a as well as each of the split ports 12b are understood to have an impedance of 50 Ohm. In the context of operating as a splitter, the active power splitter-combiner 70 is based upon the common main transistor and multiple cascode transistors. However, in the context of operating as a combiner, the functionality is based upon multiple main transistors with a common cascode transistor. Due to their dual roles, the transistor M1 may be referred to more generally as a primary transistor and the transistors M2, M3, M4, and M5 may be referred to more generally as secondary transistors. Thus, when operating as a splitter, the primary transistor M1 may also be referred to as the common main transistor and the secondary transistors M2, M3, M4, and M5 may be referred to as the cascode transistors. When operating as a combiner, the secondary transistors M2, M3, M4, and M5 may be referred to as the main transistors while the primary transistor M1 may be referred to as the common cascode transistor.

In further detail, the sources of the secondary transistors M2, M3, M4, and M5 are connected to the drain of the primary transistor M1. The drains of the secondary transistors are connected to a matching network, with the drain of the secondary transistor M2 being connected to a first matching network 72a comprised of the inductor L1 and the capacitor C7, and then to the first split port 12b-1. The drain of the secondary transistor M3 is connected to a second matching network 72b comprised of the inductor L2 and the capacitor C8, and then to the second split port 12b-2. The drain of the secondary transistor M4 is connected to a third matching network 72c comprised of the inductor L3 and the capacitor C9, and then to the third split port 12b-3. The drain of the secondary transistor M5 is connected to a fourth matching network 72d comprised of the inductor L4 and the capacitor C10 and then to the fourth split port 12b-4. The matching networks 72 may serve input matching functions when the active power splitter-combiner 70 is operating as a combiner, and output matching functions when the active power splitter-combiner 70 is operating as a splitter.

Each of the secondary transistors, and specifically the gates thereof, are connected to a bias supply voltage along with a bypass capacitor. For instance, the gate of the secondary transistor M2 is connected to the voltage source V2 through the resistor R2, along with the bypass capacitor C2. The gate of the secondary transistor M3 is connected to the voltage source V3 through the resistor R3, and there is a bypass capacitor C3. The gate of the secondary transistor M4 is connected to the voltage source V4 through the resistor R4, and there is also a bypass capacitor C4.

The secondary transistors M2, M3, M4, and M5 are each connected to a bias supply circuit 74. The matching networks 72 are each connected to the bias supply circuit 74 at a common bias supply node 76, and so the drains of the secondary transistors M2, M3, M4, and M5 are connected to the bias supply circuit 74 via a respective one of the inductors L1, L2, L3, and L4. The bias supply circuit 74 may include a voltage source V1, along with a bypass capacitor C1 that provides high isolation between the signals at the split ports 12b. The voltage source V1 is selectively connected to the secondary transistors via the transistor M7 and the transistor M11 depending on the operating mode as a combiner or a splitter.

The combined port 12a is connected to the primary transistor M1 in different ways depending on the operating mode. When operating as a splitter, the RF input signal is passed to the gate of the primary (main) transistor M1 with the switching transistor M10 activated while the switching transistor M9 is deactivated. The RF input signal may then be amplified and split to the secondary (cascode) transistors M2, M3, M4, and M5, and output to the split ports 12b. When operating as a combiner, the multiple input RF signals are input to the split ports 12b, with each being amplified and combined by the secondary (main) transistors M2, M3, M4, and M5 together with the primary (cascode) transistor M1. The switching transistor M10 is deactivated while the switching transistor M9 is activated, thereby passing the signal at the source of the primary transistor M1 to the combined port 12a.

Providing this functionality additionally involves additional components. There is a switching transistor M6, with its drain being connected to the source of the primary transistor M1. Also connected to the source of the primary transistor M1, and across the drain and source of the switching transistor M6 is the inductor L5. The source of the switching transistor M6 is connected to the source of the switching transistor M12. Connected across the switching transistor M12 is the capacitor C14, which is contemplated to have a large value of greater than 1 picofarad that has a low impedance at mm-Wave frequencies. When the switching transistor M6 is enabled, it provides a small impedance to ground for the source of the primary transistor M1. Another transistor switch M8, and the drain thereof, is connected to the junction between the inductor L5, the capacitor C14, and the sources of the switching transistors M6 and M12. The voltage source V7 is connected to the source of the switching transistor M8, the detailed functionality of which will be described more fully below.

When operating in the splitter mode, the switching transistors M8 and M11 are disabled, while the switching transistors M6, M7, and M12 are enabled. In this configuration a supply voltage (VDD) is provided to the drains of the secondary (cascode) transistors M2, M3, M4, and M5, along with a good ground connection for the source of the primary (main) transistor M1. As indicated above, the switching transistor M10 is enabled, providing the interconnection of the combined port 12a to the primary transistor M1 via a matching network 78 that is defined by the capacitor C11, the capacitor C12, and the inductor L6. In this operating mode, the matching network 78 is understood to serve input matching functions. The switching transistor M9 is disabled. The value of the capacitors and inductors in the matching networks 72 are tuned to achieve good input matching of less than −10 dB while operating in the combiner mode, as well as for output matching while operating in the splitter mode.

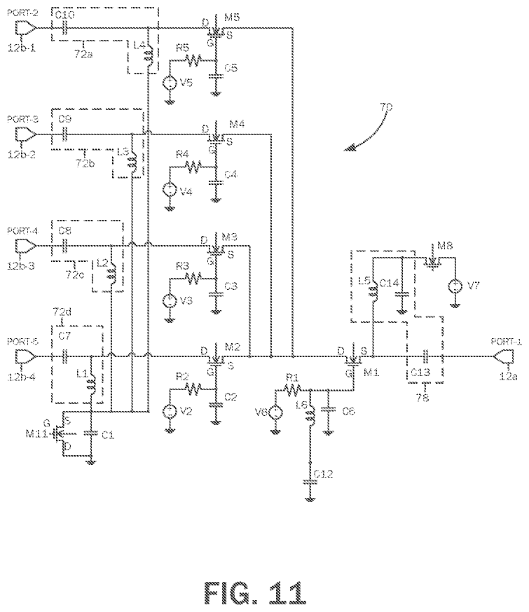

When operating in the combiner mode, the switching transistors M6, M7, M10, and M12 are disabled, while the switching transistors M8, M9 and M11 are enabled. The schematic diagram of FIG. 11 is another representation of the active power splitter-combiner 70 with certain extraneous/disabled components removed to better explain its functionality. As discussed above, the secondary (main) transistors M2, M3, M4, and M5 are connected to matching networks (input matching networks in this case) and to respective split ports 12b. The gates of each of the secondary transistors are connected to a bias supply V2, V3, V4, and V5 through resistors R2, R3, R4, and R5, respectively. The voltage levels of the bias supplies V2, V3, V4, and V5 are understood to be different from the voltages provided from the same sources but in the splitter operating mode, and rather are set to enable current mode combining of the incoming RF input signals. There are additionally bypass capacitors C2, C3, C4, and C5, also as discussed above. The matching networks 72 are each connected to the switching transistor M11, which is enabled in this operating mode.

The sources of each of the secondary (main) transistors M2, M3, M4, and M5 are connected to the drain of the primary (cascode) transistor M1. The gate of the primary transistor M1 is understood to be connected the voltage source V6 through the resistor R, the voltage supply V6 being turned on so that the primary transistor M1 conducts. In this configuration the primary transistor M1 and the secondary transistors M2, M3, M4, and M5 may effectively be two common gate transistor stages that are connected in series. The matching network 78 comprised of capacitor C13, capacitor C14, and inductor L5, which in this case is operating as an output matching network, is connected in series with the primary transistor M1. The voltage level provided by the voltage supply V7 may differ in this combination mode relative to the splitter mode. The circuit components may be tuned to achieve an overall gain between 0 to 6 dB or above when combining the signals applied to the split ports 12b that are output to the combined port 12a.

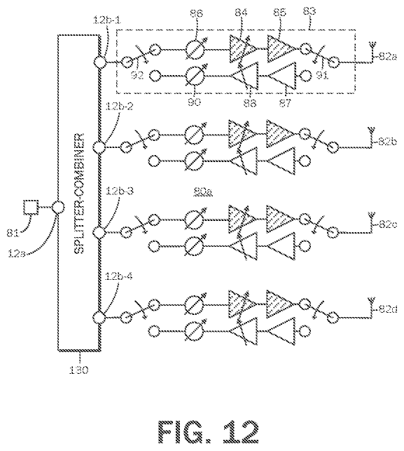

The various splitters, combiners, and splitter-combiner circuits of the present disclosure may be utilized in numerous applications. One preferred embodiment contemplates their use in 5G mm-Wave beamformer architectures. With reference to the block diagram of FIG. 12, one variation of a beamformer circuit 80a has a single RF input/output port 81 and connected to four antennas 82a, 82b, 82c, and 82d. Each antenna 82 is understood to be connected to a separate transmit/receive chain 83 that includes amplifiers and phase shifters for both a transmit signal destined for the corresponding antenna 82 as well as a receive signal from the antenna 82 to be further processed by downstream RF transceiver modules.

A single transmit RF signal may be provided to the RF input/output port and split into specific signals for each of the antennas 82 by the splitter-combiner 130. Similarly, multiple signals received by the antennas 82 may be combined into a single RF output signal by the splitter-combiner 130. As described above, the splitter-combiner 130 includes the one combined port 12a, along with multiple split ports 12b-1, 12b-2, 12b-3, and 12b-4.

In an exemplary implementation of the transmit chain circuitry, there is a transmit variable gain amplifier 84 and a transmit power amplifier 85. A transmit phase shifter 86 may apply a phase shift for the particular antenna in the array prior to amplification, and that may also be part of the transmit chain circuitry.

The receive chain circuitry may include a receive low noise amplifier 87 that receives a weak incoming signal from the antenna 82 and amplifies the same for the receive variable gain amplifier 88. A phase shift may be applied after to the receive signal amplification, and so there may be a receive phase shifter 90 connected to the output of the receive variable gain amplifier 88. These components are understood to define the receive chain circuitry.

The signal path for the transmit signals and the receive signals are controlled at both the antenna end and the splitter/combiner end. As such, there may be an antenna-side switch 91 that switches the connection to/from the antenna 82 between the output of the transmit power amplifier 85 (i.e, the transmit chain circuitry) and the input of the receive low noise amplifier 87 (i.e., the receive chain circuitry). Similarly, there may be a splitter/combiner-side switch 92 that switches the connection to/from the splitter-combiner 130 between the input to the transmit phase shifter 86 and the output from the receive phase shifter 90. Each of the split ports 12b may be connected to a separate antenna 82 over a separate and independent transmit/receive chain 83.

The embodiments of integrated splitter/combiners may be utilized for the splitter-combiner 130 of the beamformer circuit 80a. In a preferred, though optional embodiment, the splitter/combiner may utilize the passive power splitter-combiner 10 described above with reference to the schematic diagram of FIG. 1. Alternatively, the active power splitter-combiner 60 described above with reference to the schematic diagram of FIG. 9, or the active power splitter-combiner 70 also described above with reference to the schematic diagram of FIG. 10 may be utilized.

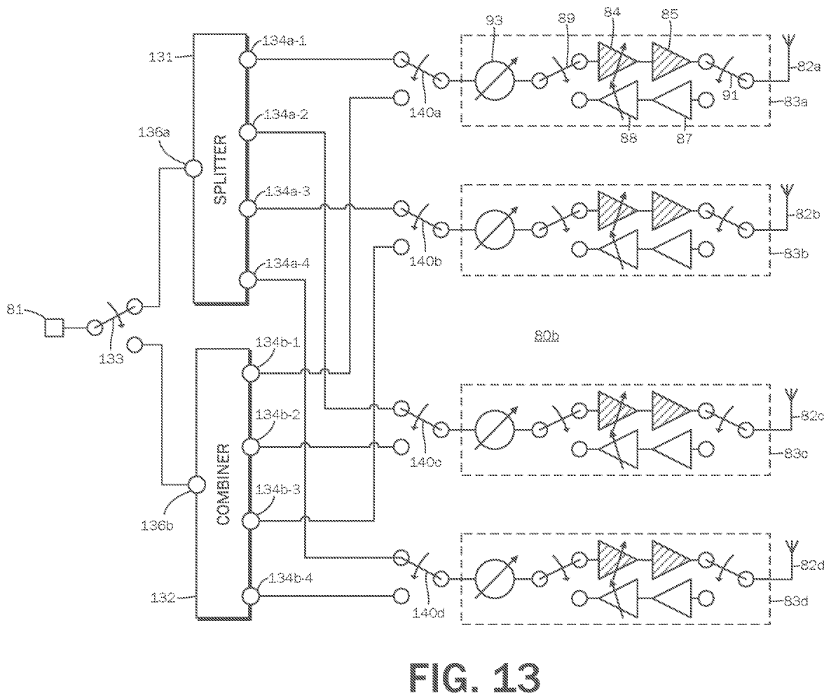

The block diagram of FIG. 13 illustrates another variation of a beamformer circuit 80, also with a single RF input/output port 81 and connectible to four antennas 82a, 82b, 82c, and 82d. There are multiple transmit/receive chains 83 that amplify and apply phase shifts to both the received signal and the transmit signal. Again, the transmit/receive chain 83 includes transmit chain circuitry including the transmit variable gain amplifier 84 and the transmit power amplifier 85. A common phase shifter 93 may apply a phase shift for the particular antenna in the array prior to amplification. The receive chain circuitry may include the receive low noise amplifier 87 that receives a weak incoming signal from the antenna 82 and amplifies the same for the receive variable gain amplifier 88. A phase shift may be applied after to the receive signal amplification, and the common phase shifter 93 is utilized.

The signal path for the transmit signals and the receive signals are controlled at both the antenna end and the phase shifter end. As such, there is the antenna-side switch 91 that switches the connection to/from the antenna 82 between the output of the transmit power amplifier 85 (i.e., the transmit chain circuitry) and the input of the receive low noise amplifier 87 (i.e., the receive chain circuitry). Similarly, there may be a phase shifter-side switch 89 that selectively connects the common phase shifter 93 to either the input of the transmit variable gain amplifier 84 or the output of the receive variable gain amplifier 88.

The illustrated embodiment contemplates the use of a separate splitter 131 and combiner 132. In this regard, the splitter 131 is understood to have four split output ports 134a-1, 134a-2, 134a-3, and 134a-4, while the combiner 132 has four split input ports 134b-1, 134b-2. 134b-3, and 134b-4. The splitter 131 has a single combined input port 136a, while the combiner 132 has a single combined output port 136b. The connection between the combined ports 136 and the RF input/output port 81 are made by a switch 133. When an RF input signal is being passed to the RF input/output port 81, it is routed to the single combined input port 136a of the splitter 131 via the switch 133 establishing such connection. On the other hand, when a combined RF output signal from the combiner 132 is to be passed to the RF input/output port 81, the switch 133 establishes the connection to the single combined output port 136b.

The transmit/receive chains 83 may be selectively connectible to a given one of the split output ports 134a of the splitter 131 or a given one of the split input ports 134b of the combiner 132. To this end, there may be a series of splitter-combiner selector switches 140, one for each of the transmit/receive chains 83. The first splitter-combiner selector switch 140a selectively connects the first transmit/receive chain 83a to either the first split output port 134a-1 or the first split input port 134b-1. The second splitter-combiner selector switch 140b selectively connects the second transmit/receive chain 83b to either the second split output port 134a-2 or the second split input port 134b-2. The third splitter-combiner selector switch 140c selectively connects the third transmit/receive chain 83c to either the third split output port 134a-3 or the third split input port 134b-3. Lastly, the fourth splitter-combiner selector switch 140d selectively connects the fourth transmit/receive chain 83d to either the fourth split output port 134a-4 or the fourth split input port 134b-4.

The embodiments of standalone splitters and combiners may be utilized for the splitter 131 or the combiner 132. Preferably, though optionally, the splitter 131 may utilize the passive power splitter-combiner 10 described above in the context of the schematic diagram of FIG. 1 for the transmit chain, while the combiner 132 may utilize the active power combiner 50 described above with reference to FIG. 7 for the receive chain. In another embodiment, the splitter 131 may utilize the active power splitter 30 or 30′ described above with reference to FIG. 6 and FIG. 7, while the combiner 132 may utilize the passive power splitter-combiner 10 shown in FIG. 1.

The splitters, combiners, and splitter-combiners disclosed herein are contemplated to have significantly reduced physical footprints and associated losses. These circuits may be implemented within a beamformer RF integrated circuit, or as a separate standalone integrated circuit for use in large-size phased array antenna systems. The costs associated with the circuits of the present disclosure are envisioned to be much lower, especially relative to existing ceramic-based power splitters, combiners, and splitter-combiners. Phased array antenna systems utilizing the embodiments of the present disclosure are envisioned to require fewer laminate layers instead of such circuits being placed on the laminate substrate. This is contemplated to further reduced costs. The resistive components otherwise necessary for laminate-based Wilkinson-type splitter-combiners can be eliminated, and is another basis for reduced footprint and cost. Although embodiments of the present disclosure have been considered in the context of 5G mm-Wave beamformer architectures, this is by way of example only and not of limitation. The circuits of the present disclosure may be incorporated into any other suitable device. Furthermore, and along these lines, the operating frequencies and exemplary component values were specific to 5G mm-Wave systems, though it will be appreciated that the splitters, combiners, and splitter-combiners may be adapted for other operating frequencies with the appropriate tuning of the components.

The particulars shown herein are by way of example and for purposes of illustrative discussion of the embodiments of the present disclosure only and are presented in the cause of providing what is believed to be the most useful and readily understood description of the principles and conceptual aspects. In this regard, no attempt is made to show details with more particularity than is necessary, the description taken with the drawings making apparent to those skilled in the art how the several forms of the present disclosure may be embodied in practice.

1. A power splitter-combiner with a combined port and a plurality of split ports, comprising:
a first coupled inductor pair with each inductor connected to the combined port;
a second coupled inductor pair with each inductor connected to a first one of the inductors of the first coupled inductor pair, a first one the inductors of the second coupled inductor pair being connected to a first one of the plurality of split ports, and a second one of the inductors of the second coupled inductor pair being connected to a second one of the plurality of split ports; and
a third coupled inductor pair with each inductor connected to a second one of the inductors of the first coupled inductor pair, a first one of the inductors of the third coupled inductor pair being connected to a third one of the plurality of split ports, and a second one of the inductors of the third coupled inductor pair being connected to a fourth one of the plurality of split ports.

2. The power splitter-combiner of claim 1, wherein an inductance value of a first chain of inductors from the combined port to one of the plurality of split ports is equivalent to another inductance value of a second chain of inductors from the combined port to another one of the plurality of split ports.

3. The power splitter-combiner of claim 1, further comprising:
a resistor-capacitor network connected across the second coupled inductor pair and the third coupled inductor pair, a capacitor of the resistor-capacitor network defining a parallel resonance with the first coupled inductor pair.

4. The power splitter-combiner of claim 1, further comprising:
a first split port resistor-capacitor network connected across the inductors of the second coupled inductor pair, a capacitor of the first split port resistor-capacitor network defining a parallel resonance with the second coupled inductor pair; and
a second split port resistor-capacitor network connected across the inductors of the third coupled inductor pair, a capacitor of the second split port resistor-capacitor network defining a parallel resonance with the third coupled inductor pair.

5. The power splitter-combiner of claim 1, further comprising:
a capacitor connected to the first coupled inductor pair and the combined port.

6. The power splitter-combiner of claim 1, wherein each of the combined port and the split ports define a 50-ohm impedance.

7. The power splitter-combiner of claim 6, wherein
the first coupled inductor pair equally splits signal power between the second coupled inductor pair and the third coupled inductor pair;
the second coupled inductor pair equally splits signal power between the first one of the inductors of the second coupled inductor pair and the second one of the inductors of the second coupled inductor pair; and
the third coupled inductor pair equally splits signal power between the first one of the inductors of the third coupled inductor pair and the second one of the inductors of the third coupled inductor pair.

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. A phased array beamformer circuit connectible to an array of antenna elements, comprising:
a radio frequency input-output port;
one or more antenna ports each connectible to a respective one of the antenna elements;
one or more transmit/receive circuits including a transmit signal chain and a receive signal chain; and
a splitter-combiner with a combined port connected to the RF input-output port, and one or more split ports each connected to a respective one of the transmit/receive circuits, the splitter-combiner including:
a first coupled inductor pair with each inductor connected to the combined port;
a second coupled inductor pair with each inductor connected to a first one of the inductors of the first coupled inductor pair, a first one the inductors of the second coupled inductor pair being connected to a first one of the split ports, and a second one of the inductors of the second coupled inductor pair being connected to a second one of the split ports; and
a third coupled inductor pair with each inductor connected to a second one of the inductors of the first coupled inductor pair, a first one of the inductors of the third coupled inductor pair being connected to a third one of the split ports, and a second one of the inductors of the third coupled inductor pair being connected to a fourth one of the split ports.

26. The phased array beamformer circuit of claim 25, wherein an inductance value of a first chain of inductors from the combined port to one of the plurality of split ports is equivalent to another inductance value of a second chain of inductors from the combined port to another one of the plurality of split ports.

27. The phased array beamformer circuit of claim 25, further comprising:
a resistor-capacitor network connected across the second coupled inductor pair and the third coupled inductor pair, a capacitor of the resistor-capacitor network defining a parallel resonance with the first coupled inductor pair.

28. The phased array beamformer circuit of claim 25, further comprising:
a first split port resistor-capacitor network connected across the inductors of the second coupled inductor pair, a capacitor of the first split port resistor-capacitor network defining a parallel resonance with the second coupled inductor pair; and
a second split port resistor-capacitor network connected across the inductors of the third coupled inductor pair, a capacitor of the second split port resistor-capacitor network defining a parallel resonance with the third coupled inductor pair.

29. The phased array beamformer circuit of claim 25, further comprising:
a capacitor connected to the first coupled inductor pair and the combined port.

30. The phased array beamformer circuit of claim 25, wherein each of the combined port and the split ports define a 50-ohm impedance.

31. The phased array beamformer circuit of claim 30, wherein
the first coupled inductor pair equally splits signal power between the second coupled inductor pair and the third coupled inductor pair;
the second coupled inductor pair equally splits signal power between the first one of the inductors of the second coupled inductor pair and the second one of the inductors of the second coupled inductor pair; and
the third coupled inductor pair equally splits signal power between the first one of the inductors of the third coupled inductor pair and the second one of the inductors of the third coupled inductor pair.

32. (canceled)

33. (canceled)

34. (canceled

35. (canceled)

36. (canceled)
